(19) United States
(12) Patent Application Publication
(10) Pub. No.: US 2025/0199413 A1
(43) Pub. Date: Jun. 19, 2025

(54) ILLUMINATION SYSTEM, RADIATION SOURCE APPARATUS, METHOD FOR ILLUMINATING A RETICLE, AND LITHOGRAPHY SYSTEM

(71) Applicant: Carl Zeiss SMT GmbH, Oberkochen (DE)

(72) Inventor: Stig BIELING, Aalen (DE)

(21) Appl. No.: 19/068,695

(22) Filed: Mar. 3, 2025

Related U.S. Application Data
(63) Continuation of application No. PCT/EP2023/074203, filed on Sep. 4, 2023.

(30) Foreign Application Priority Data
Sep. 9, 2022 (DE) 10 2022 209 465.4

(51) Int. Cl. G03F 7/00; G02B 3/00; G02B 19/00

(52) U.S. Cl. CPC G03F 7/70075; G02B 3/0056; G02B 19/0009; G03F 7/7005; G03F 7/7015

(57) ABSTRACT

An illumination system for a lithography system, such as a projection exposure apparatus, for illuminating a reticle of the lithography system with a used radiation from a radiation source apparatus, comprises an optics device having at least one optical element and at least one mixing device. An interface device is provided for input coupling a plurality of individual radiations, which form the used radiation, into the mixing device. A source étendue of the radiation source apparatus fills at least 50 percent, such as at least 80 percent, of an optics étendue of the optics device and/or mixing device.

### CROSS-REFERENCE TO RELATED APPLICATIONS

The present application is a continuation of, and claims benefit under 35 USC 120 to, international application No. PCT/EP2023/074203, filed Sep. 4, 2023, which claims benefit under 35 USC 119 of German Application No. 10 2022 209 465.4, filed Sep. 9, 2022. The entire disclosure of each of these applications is incorporated by reference herein.

### FIELD

The disclosure relates to an illumination system for a lithography system, such as for a projection exposure apparatus, for illuminating a reticle of the lithography system with a used radiation from a radiation source apparatus, comprising an optical unit having at least one optical element and at least one mixing device. The disclosure also relates to a radiation source apparatus for generating and outputting used radiation for a lithography system, such as for a projection exposure apparatus. The disclosure further relates to a method for illuminating a reticle of a lithography system, such as of a projection exposure apparatus, using a used radiation. The disclosure also relates to a lithography system, such as a projection exposure apparatus, having a radiation source apparatus and/or an illumination system for illuminating a reticle with a used radiation.

### BACKGROUND

Radiation source apparatuses for lithography systems, such as for projection exposure apparatuses, are known. The known radiation source apparatuses generally serve to form an operating radiation or used radiation for exposing a wafer plane of the lithography system. To this end, a reticle of the lithography system, for example of the projection exposure apparatus, is illuminated with the used radiation in a manner known per se.

Such a known radiation source apparatuses may not efficiently exploit an optics étendue or étendue provided by the projection exposure apparatus.

This may result in a loss of intensity of the operating radiation should the operating radiation overfill the optics étendue, or else this may result in an insufficient intensity at the reticle should the used radiation not completely fill the optics étendue.

### SUMMARY

The present disclosure seeks to develop a radiation source apparatus which avoids certain disadvantages of known radiation sources and for example allows efficient full illumination of a reticle.

The present disclosure also seeks to develop an illumination system which avoids certain disadvantages known illumination systems and for example allows efficient full illumination of a reticle.

In an aspect, the disclosure provides an illumination system for a lithography system, such as for a projection exposure apparatus, for illuminating a reticle of the lithography system with a used radiation from a radiation source apparatus. The illumination system comprises an optics device having at least one optical element and at least one mixing device. An interface device is provided for input coupling a plurality of individual radiations, which form the used radiation, into the mixing device. A source étendue of the radiation source apparatus fills at least 50 percent, such as at least 80 percent, of an optics étendue of the optics device and/or mixing device

In an aspect, the disclosure provides a radiation source apparatus for generating and outputting used radiation for a lithography system, such as a projection exposure apparatus. A plurality of source modules are provided for generating individual radiations, the individual radiations forming the used radiation

The present disclosure seeks to develop a method for illuminating a reticle which avoids certain disadvantages of known methods and for example allows efficient full illumination of the reticle.

According to the disclosure, this object is achieved by a method having the features specified in claim 33.

In an aspect, the disclosure provides a method for illuminating a reticle of a lithography system, such as a projection exposure apparatus, with a used radiation. Individual radiations for forming the used radiation are generated by a plurality of source modules. The individual radiations are input coupled into a mixing device of the projection exposure apparatus.

In an aspect, the disclosure provides a lithography system, such as a projection exposure apparatus, having a radiation source apparatus and/or an illumination system for illuminating a reticle with a used radiation. The radiation source apparatus can a radiation source apparatus according to the disclosure. The illumination system can be an illumination system according to the disclosure. The reticle can be illuminated using a method according to the disclosure.

In a radiation source apparatus according to the disclosure for generating and outputting a used radiation for a lithography system, such as for a projection exposure apparatus, the disclosure provides for a plurality of source modules for generating individual radiations, with the individual radiations forming the used radiation.

For example, provision can be made for the individual radiations to jointly form the used radiation and/or for the individual radiations to illuminate at least approximately the same location on a reticle of the projection exposure apparatus.

As a result of using a plurality of source modules, an optics étendue of downstream devices of the lithography system can be fully illuminated in an efficient manner via the radiation source apparatus according to the disclosure. By using a plurality of source modules, the used radiation can be generated in a manner adapted best to the optics étendue by combining or focusing the individual radiations.

In a development of the radiation source apparatus according to the disclosure, provision can be made for two source modules to be provided.

The inventor has determined that a total of exactly two source modules can be superior to a greater number of source modules in terms of efficiency. Even though a very high number of source modules allows a geometry of the downstream étendue or optics étendue to be covered particularly well, a total of two source modules was surprisingly found to be superior to other solutions in terms of the intensity of arriving at the reticle.

In a development of the radiation source apparatus according to the disclosure, provision can be made for the source modules to be switchable at least partly independently.

Independent switchability of the source modules can be desirable in that the number of source modules involved is adjustable depending on the desired illumination setting at the reticle, which is to say in relation to a beam angle distribution at the location of the reticle in the downstream projection exposure apparatus.

By way of example, switching on only one source module may be desirable for smaller illumination settings since the influence of the second source module would only entail costs but not contribute to an improvement in the exposure result.

In a development of the radiation source apparatus according to the disclosure, provision can be made for a control device to be provided for switching the source modules.

The control device can allow the switching of the source modules to be controlled in such a way that the above-described adaptation to the respectively used illumination settings of the projection exposure apparatus can be implemented in fully automated fashion.

The control device may be configured to determine the number N of light source images.

The number of light source images (number N) that can be used in a meaningful way depends on, firstly, a ratio of the optics étendue E_{S} to a source étendue E_{Q}. Secondly, the meaningful number N of light source images also depends on a degree of partial coherence σ to be set, as specified in formula (1).

$$N = \frac{{σ}^{2} {E}_{s}}{{E}_{Q}} \qquad ( 1 )$$

In a development of the radiation source apparatus according to the disclosure, provision can be made for the source modules to be arranged such that the used radiation is output from the parallel and spaced-apart individual radiations of the source modules.

Within the scope of the disclosure, parallel means that the beam paths of the individual radiations and/or single beam apertures of the individual radiations emerge from one another by way of a parallel shift. For example, each individual radiation may also consist of a convergent and/or divergent light beam.

A parallel and spaced-apart formation of the individual radiations of the source modules can be desirable since this can allow the given angle distribution of the illumination setting to be observed at the reticle of the lithography system or projection exposure apparatus. Unwanted deviations of the angle distribution at the reticle may arise in the case of oblique propagation of the individual radiations with respect to one another.

A spaced-apart formation of the individual radiations can be desirable in that these can be guided away from the source modules directly and without the use of further optical units. That is to say, there is no need to adopt any further measures for focusing the individual radiations.

If the individual radiations are formed in parallel and spaced apart, then an overlap of images of the source modules at an entrance site into the projection exposure apparatus can be avoided. In the case of parallel and spaced-apart individual radiations, it is therefore desirable if the control device is configured to set the number of source modules to be used, in such a way that a usable power of all source modules ηN is greater than a usable power of an individual source module η0.

By way of the control device, the number of actually used light sources or source modules can then be made dependent on a respective situation or embodiment of the downstream projection exposure apparatus.

In a development of the radiation source apparatus according to the disclosure, provision can be made for a positioning device to be provided for the purpose of positioning the source modules.

For example, in conjunction with switchably embodied source modules and the control device, the positioning device can enable such a positioning of the source modules, for example of the switched-on source modules, that the greatest amount of light from the source modules can be input coupled or is able to be input coupled into the projection exposure apparatus as used radiation.

In a development of the radiation source apparatus according to the disclosure, provision can be made for the source modules to be positionable at least partly independently of one another.

Independent positionability of the source modules can be desirable in that a position of the source modules can be flexibly adapted to the desired full reticle illumination.

Provision can be made for the positioning device to be configured to position the source modules at least partly independently of one another.

In a development of the radiation source apparatus according to the disclosure, provision can be made for the source modules to each comprise
one or more parabolic mirrors and/or ellipsoid mirrors for aligning the individual radiation, and/or
one or more spectral filters for filtering the individual radiation, and/or
a light source, such as discharge lamps, for example mercury vapor discharge lamps, and/or
one or more optical units, such as scale zoom optical units and/or focal length zoom optical units.

By way of a suitable combination of the aforementioned features, the radiation source apparatus can be configured such that an arc of the discharge lamp is imaged by way of an ellipsoid mirror on the secondary focus thereof or in the vicinity of the secondary focus of the ellipsoid mirror.

The scale zoom optical unit arranged downstream thereof may be configured to image a secondary focus of the ellipsoid mirror on downstream components of the projection exposure apparatus, for example on a rod entrance of a mixing rod as discussed hereinbelow, or more generally on an entrance surface of the mixing device, with a different scale, depending on the setting of displaceable lens elements present as part of the scale zoom optical unit.

The optionally provided discharge lamps, for example known high-power discharge lamps, may have arcs with a length of approximately 6 mm to 10 mm. Further, the highpower discharge lamps are usually able to emit into a restricted solid angle, which can be received by the ellipsoid mirror. Further, the optionally provided discharge lamps may be configured to generate an illumination wavelength of 363 nm to 367 nm, such as 365 nm.

From analyses of the phase space at the secondary focus of the ellipsoid mirror, the inventor has determined that the known high-power discharge lamps have an étendue of approximately 200 mm²sr.

Illumination systems known, such as in a scanner configuration, can provide an étendue of approximately 400 mm²sr. Illumination systems in the stepper configuration can provide an étendue of approximately 630 mm²sr.

As a result of the above-described embodiments of the radiation source apparatus according to the disclosure, it is possible to reduce and/or avoid a formation of disjoint secondary light sources in an illumination pupil of a downstream illumination system. Dark regions in the illumination pupil are efficiently avoided by using a plurality of source modules. In other words, dark intermediate spaces in a local exit pupil are filled with radiance by the use of the radiation source apparatus by virtue of using a plurality of source modules.

Provision can be made for the radiation source apparatus to comprise at least one spectral filter which is arranged and configured for joint filtering of the plurality of individual radiations.

Provision can be made for the radiation source apparatus to comprise one or more parabolic mirrors and/or ellipsoid mirrors for aligning a plurality of individual radiations and/or provision can be made for a plurality of source modules to share one parabolic mirror and/or ellipsoid mirror and/or one optical unit.

Provision can be made for the source modules to each comprise a plurality of light sources.

In a development of the radiation source apparatus according to the disclosure, provision can be made of a mixing device for mixing the used radiation and having an entrance surface.

The use of a mixing device enables an efficient homogenization of the used radiation. If, as in the present case, the used radiation is formed by a plurality of individual radiations, then the mixing device facilitates mixing or homogenization of the used radiation.

A geometry of the entrance surface and/or an exit surface of the mixing device can be determined by a desired field shape at the reticle.

As described hereinbelow, the mixing device may be embodied as a mixing rod and/or fly's eye condenser. In these cases, a geometry of the entrance surface and/or exit surface of the mixing rod or of a field honeycomb of the fly's eye condenser can be determined by the desired field shape of the used radiation at the reticle.

In a development of the radiation source apparatus according to the disclosure, provision can be made for an interface device to be provided for positioning and aligning the individual radiations.

The presence of the interface device can be desirable for efficient input coupling of the plurality of individual radiations into the downstream beam path of the projection exposure apparatus, for example into the mixing device. Individual conditions at the source modules, for example a spatial extent or fastening options, can be compensated for by an appropriate design of the interface device, with the result that the most optimized input coupling into the mixing device possible is enabled.

In a development of the radiation source apparatus according to the disclosure, provision can be made for the interface device to be configured to input couple the used radiation into the mixing device.

The interface device can be desirable when input coupling the used radiation, formed from the individual radiations, into the mixing device for example, since the used radiation can be further adapted to the entrance surface of the mixing device by way of the interface device.

In a development of the radiation source apparatus according to the disclosure, provision can be made for the individual radiations to be composed to form the used radiation in such a way that, when the used radiation is incident on the entrance surface of the mixing device, the cross-sectional area of the used radiation is formed by a plurality of individual radiations running adjacently and parallel to one another, with the individual radiations optionally not overlapping.

The above-described embodiment allows the formation of an efficient reticle illumination in a relatively simple manner.

In a development of the radiation source apparatus according to the disclosure, provision can be made for the mixing device to be in the form of a mixing rod.

An embodiment of the mixing device as a mixing rod can be desirable in that mixing rods represent a known and tested option for homogenizing the used radiation and, further, can easily be introduced into a beam path of a projection exposure apparatus.

Provision can be made for the mixing rod to be made from two at least approximately orthogonal mixing rod portions and a prism device, with the prism device being configured to transfer the used radiation from a first mixing rod portion to a second mixing rod portion. This yields an around-the-corner configuration of the mixing rod, facilitating making the beam path of the projection exposure apparatus more compact.

In a development of the radiation source apparatus according to the disclosure, provision can be made for
the source modules to be arranged in spaced apart fashion and, in the direction of their individual radiations, parallel to one another and/or
the interface device to comprise four or more deflection mirrors, with the deflection mirrors being at least partly arranged parallel to one another such that a distance between the individual radiations post incidence on the deflection mirrors is reduced and/or
the deflection mirrors to be arranged such that the individual radiations are guided at right angles to the entrance surface of the mixing rod.

The above-described features may be realized on their own. However, a joint realization of the features on the basis of the and operation can be desirable.

An elongated embodiment can be realized by way of the above-described arrangement of the source modules and formation of the interface device. This may be desirable, depending on the geometric situation in the projection exposure apparatus.

In a development of the radiation source apparatus according to the disclosure, provision can be made for
the source modules to be arranged in spaced apart fashion and, in the direction of their individual radiations, in antiparallel and laterally offset fashion and/or
the interface device to comprise two or more prisms, the prisms being arranged such that a respective first side face of the prisms is arranged at least approximately parallel to the entrance surface of the mixing rod and a respective second side face is arranged at least approximately perpendicular to the individual radiations, and a respective third side face is arranged such that the individual radiations are guided from the respective second side face to the respective first side face within the respective prism.

The above-described embodiment of the arrangement of the components of the radiation source apparatus allows a flexible adaptation in the case of given installation space conditions.

In a development of the radiation source apparatus according to the disclosure, provision can be made for the source modules to be arranged in spaced apart fashion and, in the direction of their individual radiations, to be tilted vis-à-vis one another and vis-à-vis a central plane of the mixing rod such that their respective scale zoom optical units and/or focal length zoom optical units comprise a common pupil plane and/or the interface device comprises a Fourier optics device as an input coupling group, the latter being configured to image the individual radiations onto the entrance surface of the mixing rod, wherein
the interface device can comprise a deflection mirror, the deflection mirror being arranged such that the individual radiations are aligned with the Fourier optics device, or
the interface device comprises a deflection device, with the deflection device having optical powers that act on the individual radiations, for example for the purpose of adapting back focal lengths, with the deflection device being arranged such that the individual radiations are aligned with the Fourier optics device.

Depending on the installation space situation in the projection exposure apparatus, the above-described embodiments enable simple and space-saving solutions.

Provision can be made for the individual radiations to be incident on the deflection mirror at an angle of 1° to 30°, such as 2° to 20°.

In a development of the radiation source apparatus according to the disclosure, provision can be made for the individual radiations to be able to be input coupled into the mixing rod along a longitudinal axis of the mixing rod.

Input coupling the individual radiations into the mixing rod along the longitudinal axis can be desirable in that, as a result, particularly low losses are to be expected during a passage through the front entrance surface.

In a development of the radiation source apparatus according to the disclosure, provision can be made for the mixing device to be in the form of a fly's eye condenser with a field honeycomb device, a pupil honeycomb device, and a downstream secondary Fourier optics device.

An embodiment of the mixing device as a fly's eye condenser having the field honeycomb device, the pupil honeycomb device, and the secondary Fourier optics device can be desirable in that this renders realizable relatively efficient mixing in a relatively small installation space.

In a development of the radiation source apparatus according to the disclosure, provision can be made for the source modules to each comprise at least one focal length zoom optical unit.

In contrast to the above-described embodiment which resorts to a mixing rod, a focal length zoom optical unit with downstream Fourier optics, the secondary Fourier optics device, can be used if a fly's eye condenser is used.

Provision can be made for the positioning device to be designed for the relative rotation of the source modules with respect to one another. An available space between individual channels of the fly's eye condenser can be filled by a relative rotation of the source modules with respect to one another.

Provision can be made for the positioning device to be configured to carry out a translation and/or a rotation of the source modules with respect to one another.

Provision can be made for the interface device to be configured to merge the individual radiations upstream of the field honeycomb device. For example, provision can be made for the interface device to have a deflection mirror to this end.

The field honeycomb device may be in the form of a field honeycomb plate.

Provision can be made for a respective output back focal length of the respective focal length zoom optical unit to be formed greater than an image diameter of the used radiation. As a result of a relatively large choice of the output back focal length of the focal length zoom optical unit, it is possible to ensure a sufficiently large distance between the source modules.

In a development of the radiation source apparatus according to the disclosure, provision can be made for the focal length zoom optical units to comprise a retrofocus device.

By using the retrofocus device, the back focal length of the focal length zoom can be chosen to be relatively large in a relatively simple manner.

In a development of the radiation source apparatus according to the disclosure, provision can be made for the source modules to be arranged spaced apart and, in the direction of their individual radiations, tilted vis-à-vis one another and vis-à-vis an optical axis, in such a way that
the individual radiations are imaged into the field honeycomb device and/or
their respective focal length zoom optical units have a common pupil plane.

The above-described arrangement was found to be desirable when used in conjunction with a fly's eye condenser as a mixing device since the tilt of the source modules vis-à-vis the optical axis can be desirable to fill up gaps in the illumination pupil when a fly's eye condenser is used.

Provision can be made for the individual radiations to be incident on the field honeycomb plate at an angle of 1° to 40°, for example 5° to 30°, with respect to the optical axis of the field honeycomb plate.

In a development of the radiation source apparatus according to the disclosure, provision can be made for
the source modules to be arranged in spaced apart fashion and, in the direction of their individual radiations, in antiparallel fashion and/or
the interface device to comprise a deflection device having at least two deflection mirrors, the deflection mirrors being arranged such that the individual radiations are merged on the field honeycomb device in a manner tilted with respect to the optical axis, wherein
the individual radiations are imaged into the field honeycomb device and/or
their respective focal length zoom optical units have a common pupil plane.

The above-described configuration can be suitable if an oblique arrangement of all source modules vis-à-vis the optical axis can be undesirable for reasons of space. An oblique incidence of the individual radiations on the fly's eye condenser can be obtained with efficient use of the installation space by way of the appropriately adapted interface device.

In a development of the radiation source apparatus according to the disclosure, provision can be made for the interface device to comprise a deflection mirror, the deflection mirror being arranged such that the individual radiations are merged on the field honeycomb device.

The above-described configuration facilitates the formation of the embodiment of the radiation source apparatus described hereinabove, in which the source modules are arranged in spaced apart fashion and, in the direction of their individual radiations, in antiparallel and laterally offset fashion.

In a development of the radiation source apparatus according to the disclosure, provision can be made for a back focal length of the respective focal length zoom optical unit to correspond to at least one image diameter, such as three times the image diameter, for example ten times the image diameter of the respective individual radiations on the field honeycomb device.

The aforementioned choice of the back focal length of the respective focal length zoom optical unit was found to be suitable for obtaining a large operation area when positioning the source modules.

Provision can be made for the back focal length to be between 10 mm and 2000 mm, such as between 20 mm and 1200 mm, and/or to be adjustable.

The disclosure further relates to an illumination system having the features specified in claim 1.

The illumination system according to the disclosure for a lithography system, for example for a projection exposure apparatus, serves to illuminate a reticle of the lithography system with a used radiation from a radiation source apparatus, and comprises an optical unit having at least one optical element and at least one mixing device. According to the disclosure, an interface device is provided for input coupling a plurality of individual radiations, which form the used radiation, into the mixing device, wherein a source étendue of the radiation source apparatus to fill at least 50 percent, such as at least 80 percent, of an optics étendue of the optics device and/or mixing device.

The use of the interface device can be desirable in that the individual radiations, which may originate from different sources or source modules, can be adapted to the desired properties and geometries prevalent at the site of entry into the mixing device.

As a result, the illumination system enables the full illumination of a larger portion of the system étendue than in the case of illumination systems known.

Within the scope of the disclosure, a fill of at least 50 percent of the optics étendue by the source étendue was found to be a desirable compromise between a number of individual radiations used and an improvement in the light intensity at the reticle obtained thereby.

In a development of the illumination system according to the disclosure, provision can be made for the mixing device to be in the form of a mixing rod.

The use of a mixing rod as a mixing device can be desirable in that mixing rods are known as reliable and inexpensive mixing devices.

In a development of the illumination system according to the disclosure, provision can be made, at an entrance surface of the mixing rod, for the individual radiations to be offset from one another and, with respect to an optical axis of the mixing rod, be offset parallel thereto and from one another.

A parallel and offset arrangement of the individual radiations at the entrance surface of the mixing rod can be desirable in that the used radiation can fill an étendue of the illumination system or an optics étendue to a relatively complete extent.

In a development of the illumination system according to the disclosure, provision can be made for the mixing device to be in the form of a fly's eye condenser with a field honeycomb device, a pupil honeycomb device, and a downstream secondary Fourier optics device.

The use of a fly's eye condenser can be desirable in that this allows the mixing device to be formed relatively efficiently and in installation space-saving fashion.

In a development of the illumination system according to the disclosure, provision can be made for the interface device to be configured to input couple a plurality of individual radiations of the used radiation into the fly's eye condenser, with the individual radiations being tilted with respect to one another and with respect to an optical axis of the fly's eye condenser at the field honeycomb device and being merged there.

When a fly's eye condenser is used as a mixing device, filling out the étendue of the illumination system can be increased, for example, by virtue of the plurality of individual radiations being supplied to the fly's eye condenser in tilted fashion via the interface device. A merged yet, with respect to the optical axis of the fly's eye condenser, tilted alignment of the individual radiations at the site of entry into the fly's eye condenser can be desirable in that an illumination setting at a reticle of a downstream projection exposure apparatus is not impaired in comparison with a single individual radiation.

In a development of the illumination system according to the disclosure, provision can be made for the interface device to comprise at least one deflection mirror, for example with optical power, and/or at least one prism.

By using optical elements with optical power, for example deflection mirrors with optical power and/or prisms with optical power, it is possible to influence, for example lengthen, the output sections or back focal lengths or working distances of the scale zoom optical unit and/or focal length zoom optical units.

In a development of the illumination system according to the disclosure, provision can be made for the radiation source apparatus to be in the form of a radiation source apparatus according to the disclosure.

Although more desirable UV light can be formed by radiation sources known, illumination systems in scanner configuration and/or stepper configuration are limited in terms of their usable étendue. To compensate this, there is the desire for radiation sources with a high radiance. Discharge lamps, as used in an embodiment of the radiation source apparatus according to the disclosure, offer a high radiance.

The illumination system according to the disclosure can be suitable for applications in a packaging sector of semiconductor lithography. What can be decisive here is a throughput and not so much a resolution limit of the projection exposure apparatus. Using the illumination system according to the disclosure and the high irradiance and intensity at the reticle ensuing in the illumination system according to the disclosure, it is possible to attain such a high throughput by way of short illumination times.

In the illumination systems in scanner configuration and/or stepper configuration known, the optics étendue of the optical system of the illumination system is greater than that of the radiation source. This allows the use of a plurality of discharge lamps in order to increase the radiant flux and hence the system throughput or productivity of the projection exposure apparatus.

Provision can be made for that portion of the entrance pupil in a projection optical unit of a projection exposure apparatus which is usable on account of the partial coherence of the used radiation to be illuminated by the used radiation. This avoids a loss of light.

In a development of the illumination system according to the disclosure, provision can be made for a positioning device to be provided for positioning the illumination system, for example relative to the radiation source apparatus, and/or for positioning the radiation source apparatus, for example relative to the illumination system.

Provision can be made for the positioning device to be configured to rotate parts of the radiation source apparatus, for example source modules, which form the individual radiations. This can be desirable when using a fly's eye condenser, for example.

The disclosure further relates to a method for illuminating a reticle.

In a method according to the disclosure for illuminating a reticle of a lithography system, for example of a projection exposure apparatus, with a used radiation, individual radiations for forming the used radiation are generated by a plurality of source modules. According to the disclosure, the individual radiations are input coupled into a mixing device of the projection exposure apparatus.

The method according to the disclosure can be desirable in that, as a result of input coupling a plurality of individual radiations, it is possible to exploit an étendue of the projection exposure apparatus, for example of the mixing device, as completely as possible.

In a development of the method according to the disclosure, provision can be made for the source modules to be switched and/or positioned in at least partly independent fashion.

As a result of an at least partly independent control of a position and an emission state of the source modules, it is possible to obtafor examplely good illumination of the reticle.

To form the used radiation in a mixing device in the form of a fly's eye condenser having a field honeycomb device, a pupil honeycomb device, and a downstream secondary Fourier optics device in a development of the method according to the disclosure, provision can be made for the individual radiations to be input coupled in such a way that the individual radiations are tilted with respect to one another and with respect to an optical axis of the mixing rod at the field honeycomb device and are merged there.

A tilted supply of the individual radiations to the fly's eye condenser can help enable a desirable fill of the optics étendue of the mixing device.

In a development of the method according to the disclosure, provision can be made for the source modules to be switched and/or positioned in such a way that a source étendue of the used radiation fills at least 50 percent, such as at least 80 percent, of an optics étendue of the projection exposure apparatus for each utilized pupil filling.

For example, the source étendue of the used radiation may correspond to an étendue of the radiation source apparatus.

Within the scope of the disclosure, an incomplete fill of the optics étendue of 50 percent to 70 percent was found to be a desirable compromise between a loss of light and a luminous intensity at the illuminated reticle.

The disclosure further relates to a lithography system having the features specified in claim 38.

The lithography system according to the disclosure, for example a projection exposure apparatus, comprises a radiation source apparatus and/or an illumination system for illuminating a reticle with a used radiation. According to the disclosure, provision is made for the radiation source apparatus to be a radiation source apparatus according to the disclosure or one of the embodiments of the radiation source apparatus according to the disclosure and/or for the illumination system to be an illumination system according to the disclosure or one of the embodiments of the illumination system according to the disclosure and/or for the reticle to be illuminated using a method according to the disclosure and/or using one of the embodiments of the method according to the disclosure.

The lithography system according to the disclosure can be desirable in that it has a high illumination intensity at the reticle, increasing a system throughput through the lithography system.

In a development of the lithography system according to the disclosure, provision can be made for a positioning device to be provided and configured to
position the source modules relative to one another and/or relative to the illumination system, and/or
position the radiation source apparatus relative to the illumination system.

By using the positioning device, it is possible to adjust the positioning of the source modules on the basis of the illumination settings at the reticle desired during the operation of the projection exposure apparatus.

In a development of the lithography system according to the disclosure, provision can be made for the source modules to be switchable and/or positionable in such a way that the source étendue fills at least 50 percent, such as at least 80 percent, of the optics étendue for each utilized pupil filling.

Especially in the case of an incomplete fill of the optics étendue of 50 percent to 70 percent, a very good compromise ensues between a luminous intensity at the reticle and a number of source modules to be used.

Features described in conjunction with one of the subjects of the disclosure, specifically given by the radiation source apparatus according to the disclosure, the illumination system according to the disclosure, the method according to the disclosure, and the lithography system according to the disclosure, are also implementable for the other subjects of the disclosure. Likewise, features specified in conjunction with one of the subjects of the disclosure can also be understood in relation to the other subjects of the disclosure.

In addition, it should be noted that expressions such as “comprising”, “having” or “with” do not exclude any other features or steps. Further, expressions such as “a” or “the” that refer in the singular to steps or features do not exclude a plurality of features or steps—and vice versa.

However, in a puristic embodiment of the disclosure, provision may be made for the features introduced in the disclosure using the terms “comprising”, “having” or “with” to be an exhaustive enumeration. Accordingly, one or more enumerations of features can be considered to be exhaustive within the scope of the disclosure, for example when respectively considered for each claim. By way of example, the disclosure can consist exclusively of the features specified in claim 9 or 1.

It should be noted that labels such as “first” or “second”, etc. are used predominantly for reasons of distinguishability between respective apparatus or method features and are not necessarily intended to indicate that features require one another or are related to one another.

Exemplary embodiments of the disclosure will be described in detail hereinbelow with reference to the drawing.

The figures each show certain exemplary embodiments in which individual features of the present disclosure are illustrated in combination with one another. Features of one exemplary embodiment may also be implemented separately from the other features of the same exemplary embodiment, and may accordingly be readily combined by an expert to form further useful combinations and sub-combinations with features of other exemplary embodiments.

### BRIEF DESCRIPTION OF THE DRAWINGS

Elements of identical function are denoted by the same reference designations in the figures, in which:

FIG. 1 shows a meridional section of an EUV projection exposure apparatus;

FIG. 2 shows a DUV projection exposure apparatus;

FIG. 3 shows a schematic illustration of a possible embodiment of a radiation source apparatus according to the disclosure;

FIG. 4 shows a schematic illustration of a possible embodiment of a source module of the radiation source apparatus according to the disclosure;

FIG. 5 shows a schematic illustration of a possible embodiment of a radiation source apparatus according to the disclosure;

FIG. 6 shows a schematic illustration of a possible embodiment of a radiation source apparatus according to the disclosure;

FIG. 7 shows a schematic illustration of a possible embodiment of a radiation source apparatus according to the disclosure;

FIG. 8 shows a schematic illustration of a possible embodiment of a radiation source apparatus according to the disclosure;

FIG. 9 shows a schematic illustration of a possible embodiment of a radiation source apparatus according to the disclosure;

FIG. 10 shows a schematic illustration of a conventional radiation source apparatus;

FIG. 11 shows a schematic illustration of a possible embodiment of a radiation source apparatus according to the disclosure;

FIG. 12 shows a schematic illustration of a possible embodiment of a radiation source apparatus according to the disclosure;

FIG. 13 shows a schematic illustration of a possible embodiment of a radiation source apparatus according to the disclosure;

FIG. 14 shows a schematic illustration of a possible ratio of a source étendue to an optics étendue in a conventional illumination system;

FIG. 15 shows a schematic illustration of a possible ratio of a source étendue to an optics étendue in an illumination system according to the disclosure;

FIG. 16 shows a schematic illustration of a possible improvement of the use of an étendue by a radiation source apparatus according to the disclosure or an illumination system according to the disclosure in the case of a scanner configuration and a large illumination setting;

FIG. 17 shows a schematic illustration of a possible feature according to FIG. 16 in the case of a stepper configuration;

FIG. 18 shows a schematic illustration of a possible feature according to FIG. 16 in the case of a small illumination setting;

FIG. 19 shows a schematic illustration of a possible feature according to FIG. 16 in the case of a small illumination setting and a stepper configuration;

FIG. 20 shows a block diagram illustration of a possible embodiment of a method according to the disclosure; and

FIG. 21 shows a schematic illustration of a further possible embodiment of the projection exposure apparatus according to the disclosure.

### DETAILED DESCRIPTION

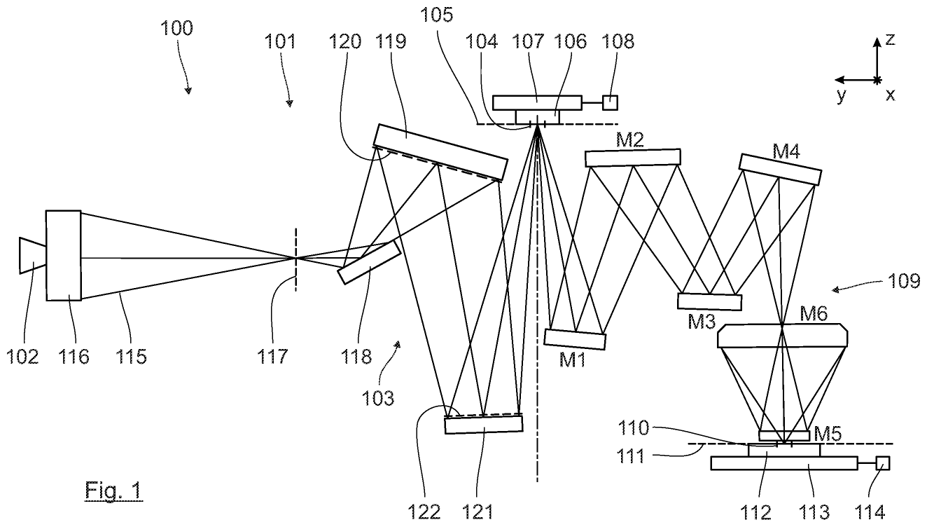

With reference to FIG. 1, certain components of a microlithographic EUV projection exposure apparatus 100 as an example of a lithography system are initially described below in exemplary fashion. The description of the basic structure of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. What is exposed here is a reticle 106 arranged in the object field 104. The reticle 106 is held by a reticle holder 107. The reticle holder 107 is displaceable for example in a scanning direction by way of a reticle displacement drive 108.

In FIG. 1, a Cartesian xyz-coordinate system is plotted to aid the explanation. The x-direction runs perpendicularly into the plane of the drawing. The y-direction runs horizontally, and the z-direction runs vertically. In FIG. 1, the scanning direction runs in the y-direction. The z-direction runs perpendicular to the object plane 105.

The EUV projection exposure apparatus 100 comprises a projection optical unit 109. The projection optical unit 109 serves for imaging the object field 104 into an image field 110 in an image plane 111. The image plane 111 extends parallel to the object plane 105. Alternatively, an angle that differs from 0° between the object plane 105 and the image plane 111 is also possible.

A structure on the reticle 106 is imaged onto a light-sensitive layer of a wafer 112 arranged in the region of the image field 110 in the image plane 111. The wafer 112 is held by a wafer holder 113. The wafer holder 113 is displaceable for example in the y-direction by way of a wafer displacement drive 114. The displacement, firstly, of the reticle 106 by way of the reticle displacement drive 108 and, secondly, of the wafer 112 by way of the wafer displacement drive 114 can be implemented so as to be mutually synchronized.

The radiation source 102 is an EUV radiation source. The radiation source 102 emits, for example, EUV radiation 115, which is also referred to below as used radiation, illumination radiation or projection radiation. For example, the used radiation 115 has a wavelength in the range between 5 nm and 30 nm. The radiation source 102 can be a plasma source, for example an LPP source (“laser produced plasma”) or a GDPP source (“gas discharged produced plasma”). It may also be a synchrotron-based radiation source. The radiation source 102 can be a free electron laser (FEL).

The illumination radiation 115 emerging from the radiation source 102 is focused by a collector 116. The collector 116 may be a collector with one or more ellipsoidal and/or hyperboloidal reflection surfaces. The at least one reflection surface of the collector 116 can be impinged upon by the illumination radiation 115 with grazing incidence (GI), which is to say with angles of incidence greater than 45°, or with normal incidence (NI), which is to say with angles of incidence less than 45°. The collector 116 can be structured and/or coated, firstly, for optimizing its reflectivity for the used radiation 115 and, secondly, for suppressing extraneous light.

Downstream of the collector 116, the illumination radiation 115 propagates through an intermediate focus in an intermediate focal plane 117. The intermediate focal plane 117 can represent a separation between a radiation source module, having the radiation source 102 and the collector 116, and the illumination optical unit 103.

The illumination optical unit 103 comprises a deflection mirror 118 and, downstream thereof in the beam path, a first facet mirror 119. The deflection mirror 118 can be a plane deflection mirror or, alternatively, a mirror with a beam-influencing effect that goes beyond the purely deflecting effect. As an alternative or in addition, the deflection mirror 118 may be in the form of a spectral filter that separates a used light wavelength of the illumination radiation 115 from extraneous light at a wavelength deviating therefrom. If the first facet mirror 119 is arranged in a plane of the illumination optical unit 103 that is optically conjugate to the object plane 105 as a field plane, it is also referred to as a field facet mirror. The first facet mirror 119 comprises a multiplicity of individual first facets 120, which are also referred to below as field facets. Only a few of these facets 120 are illustrated in FIG. 1 in exemplary fashion.

The first facets 120 may be embodied as macroscopic facets, for example as rectangular facets or as facets with an arcuate edge contour or an edge contour of part of a circle. The first facets 120 may be embodied as plane facets or alternatively as convexly or concavely curved facets.

As is known for example from DE 10 2008 009 600 A1, the first facets 120 themselves can also each be composed of a multiplicity of individual mirrors, for example a multiplicity of micromirrors. For example, the first facet mirror 119 can be embodied as a microelectromechanical system (MEMS). For details, reference is made to DE 10 2008 009 600 A1.

The illumination radiation 115 travels horizontally, which is to say in the y-direction, between the collector 116 and the deflection mirror 118.

In the beam path of the illumination optical unit 103, a second facet mirror 121 is arranged downstream of the first facet mirror 119. If the second facet mirror 121 is arranged in a pupil plane of the illumination optical unit 103, it is also referred to as a pupil facet mirror. The second facet mirror 121 can also be arranged at a distance from a pupil plane of the illumination optical unit 103. In this case, the combination of first facet mirror 119 and second facet mirror 121 is also referred to as a specular reflector. Specular reflectors are known from US 2006/0132747 A1, EP 1 614 008 B1, and U.S. Pat. No. 6,573,978.

The second facet mirror 121 comprises a plurality of second facets 122. In the case of a pupil facet mirror, the second facets 122 are also referred to as pupil facets.

The second facets 122 may likewise be macroscopic facets, which may for example have a round, rectangular or hexagonal boundary, or may alternatively be facets composed of micromirrors. In this regard, reference is likewise made to DE 10 2008 009 600 A1.

The second facets 122 may have plane reflection surfaces or alternatively reflection surfaces with a convex or concave curvature.

The illumination optical unit 103 consequently forms a double-faceted system. This fundamental principle is also referred to as a fly's eye condenser (fly's eye integrator).

It may be desirable to arrange the second facet mirror 121 not exactly in a plane that is optically conjugate to a pupil plane of the projection optical unit 109.

With the aid of the second facet mirror 121, the individual first facets 120 are imaged into the object field 104. The second facet mirror 121 is the last beam-shaping mirror or indeed the last mirror for the illumination radiation 115 in the beam path upstream of the object field 104.

In a further embodiment, not illustrated, of the illumination optical unit 103, a transfer optical unit can be arranged in the beam path between the second facet mirror 121 and the object field 104, the

transfer optical unit contributing for example to the imaging of the first facets 120 into the object field 104. The transfer optical unit may comprise exactly one mirror, but alternatively also comprise two or more mirrors, which are arranged one behind the other in the beam path of the illumination optical unit 103. For example, the transfer optical unit can comprise one or two mirrors for normal incidence (NI mirror, “normal incidence” mirror) and/or one or two mirrors for grazing incidence (GI mirror, “grazing incidence” mirror).

In the embodiment shown in FIG. 1, the illumination optical unit 103 comprises exactly three mirrors downstream of the collector 116, specifically the deflection mirror 118, the field facet mirror 119, and the pupil facet mirror 121.

The deflection mirror 118 can also be dispensed with in a further embodiment of the illumination optical unit 103, and so the illumination optical unit 103 can then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is, as a rule, only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve or any other number of mirrors Mi are likewise possible. The penultimate mirror M5 and the last mirror M6 each have a passage opening for the illumination radiation 115. The projection optical unit 109 is a twice-obscured optical unit. The projection optical unit 109 has an image-side numerical aperture which is greater than 0.5 and which can also be greater than 0.6 and, for example, can be 0.7 or 0.75.

Reflection surfaces of the mirrors Mi can be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 103, the mirrors Mi can have highly reflective coatings for the illumination radiation 115. These coatings can be designed as multilayer coatings, for example with alternating layers of molybdenum and silicon.

The projection optical unit 109 has a large object-image offset in the y-direction between a y-coordinate of a center of the object field 104 and a y-coordinate of the center of the image field 110. In the y-direction, this object-image offset can be of approximately the same magnitude as a z-distance between the object plane 105 and the image plane 111.

The projection optical unit 109 may for example have an anamorphic form. For example, it has different imaging scales βx, βy in the x- and y-directions. The two imaging scales βx, βy of the projection optical unit 109 can be (βx, βy)=(+/−0.25, +/−0.125). A positive imaging scale β means imaging without image inversion. A negative sign for the imaging scale β means imaging with image inversion.

The projection optical unit 109 consequently leads to a reduction in size with a ratio of 4:1 in the x-direction, which is to say in a direction perpendicular to the scanning direction.

The projection optical unit 109 leads to a reduction in size of 8:1 in the y-direction, which is to say in the scanning direction.

Other imaging scales are likewise possible. Imaging scales with the same signs and the same absolute values in the x-direction and y-direction are also possible, for example with absolute values of 0.125 or 0.25.

The number of intermediate image planes in the x-direction and in the y-direction in the beam path between the object field 104 and the image field 110 can be the same or can differ depending on the embodiment of the projection optical unit 109. Examples of projection optical units with different numbers of such intermediate images in the x- and y-directions are known from US 2018/0074303 A1.

In each case one of the pupil facets 122 is assigned to exactly one of the field facets 120 for forming in each case an illumination channel for illuminating the object field 104. For example, this can yield illumination according to the Köhler principle. The far field is decomposed into a multiplicity of object fields 104 with the aid of the field facets 120. The field facets 120 generate a plurality of images of the intermediate focus on the pupil facets 122 respectively assigned thereto.

By way of an assigned pupil facet 122, the field facets 120 are imaged in each case onto the reticle 106 in a manner overlaid on one another for the purpose of illuminating the object field 104. The illumination of the object field 104 is for example as homogeneous as possible. It can have a uniformity error of less than 2%. Field uniformity can be attained by overlaying different illumination channels.

The illumination of the entrance pupil of the projection optical unit 109 can be defined geometrically by way of an arrangement of the pupil facets. It is possible to set the intensity distribution in the entrance pupil of the projection optical unit 109 by selecting the illumination channels, for example the subset of pupil facets, which guide light. This intensity distribution is also referred to as illumination setting.

A likewise preferred pupil uniformity in the region of sections of an illumination pupil of the illumination optical unit 103 that are illuminated in a defined manner can be achieved by a redistribution of the illumination channels.

Further aspects and details of the illumination of the object field 104 and for example of the entrance pupil of the projection optical unit 109 are described hereinbelow.

The projection optical unit 109 may for example have a homocentric entrance pupil. The latter can be accessible. It can also be inaccessible.

The entrance pupil of the projection optical unit 109 generally cannot be illuminated exactly via the pupil facet mirror 121. The aperture rays often do not intersect at a single point when imaging the projection optical unit 109, which telecentrically images the center of the pupil facet mirror 121 onto the wafer 112. However, it is possible to find a surface area in which the spacing of the aperture rays that is determined in pairs becomes minimal. This surface area represents the entrance pupil or an area in real space that is conjugate thereto. For example, this area has a finite curvature.

The projection optical unit 109 might have different poses of the entrance pupil for the tangential beam path and for the sagittal beam path. In this case, an imaging element, for example an optical component of the transfer optical unit, should be provided between the second facet mirror 121 and the reticle 106. With the aid of this optical component, it is possible to take account of the different poses of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is arranged so as to be tilted in relation to the object plane 105. The first facet mirror 119 is arranged so as to be tilted in relation to an arrangement plane defined by the deflection mirror 118.

The first facet mirror 119 is arranged so as to be tilted in relation to an arrangement plane defined by the second facet mirror 121.

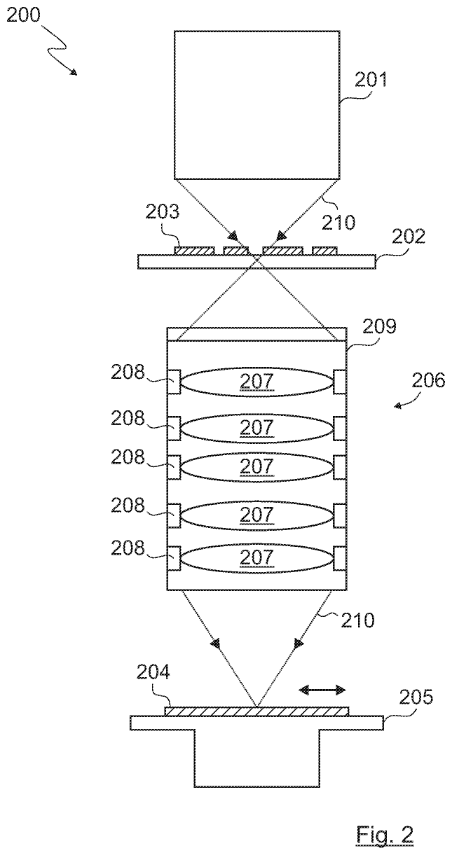

FIG. 2 shows an exemplary DUV projection exposure apparatus 200. The EUV-specific components, for example a collector mirror 116, are then not required to this end or may be substituted accordingly. However, provision can also be made for discharge lamps with collectors to be used. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving and exactly positioning the wafer 204, and an imaging device, specifically a projection optical unit 206, with a plurality of optical elements, for example lens elements 207, which are held by way of mounts 208 in a lens housing 209 of the projection optical unit 206.

As an alternative or in addition to the lens elements 207 illustrated, provision can be made of various refractive, diffractive and/or reflective optical elements, inter alia also mirrors, prisms, terminating plates and the like.

The basic functional principle of the DUV projection exposure apparatus 200 makes provision for the structures introduced into the reticle 203 to be imaged onto the wafer 204.

The illumination system 201 provides a projection beam 210 or projection radiation in the form of electromagnetic radiation, which is used for the imaging of the reticle 203 on the wafer 204. The source used for this radiation may be a laser, a plasma source or the like. The radiation is shaped in the illumination system 201 via optical elements such that the projection beam 210 has the desired properties with regard to diameter, polarization, shape of the wavefront and the like when it is incident on the reticle 203.

An image of the reticle 203 is generated via the projection beam 210 and transferred from the projection optical unit 206 onto the wafer 204 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be high-purity water, for example. Such a set-up is also referred to as immersion lithography and has an increased photolithographic resolution.

The use of the disclosure is not restricted to use in projection exposure apparatuses 100, 200, for example also not with the described structure. The disclosure is suitable for any lithography system, but for example for projection exposure apparatuses having the described structure. The disclosure is also suitable for EUV projection exposure apparatuses which have a smaller image-side numerical aperture than those described in the context of FIG. 1. For example, the disclosure is also suitable for EUV projection exposure apparatuses which have an image-side numerical aperture from 0.25 to 0.5, such as 0.3 to 0.4, for example 0.33. The disclosure and the following exemplary embodiments should also not be understood as being restricted to a specific design. The figures that follow illustrate the disclosure merely by way of example and in highly schematized form.

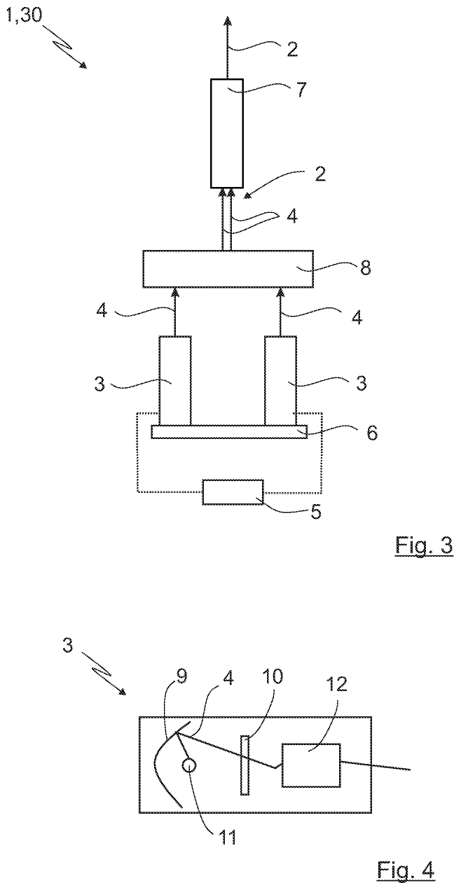

FIG. 3 shows a schematic illustration of a possible embodiment of a radiation source apparatus 1.

In the radiation source apparatus 1 for generating and outputting a used radiation 2 for a lithography system, for example for one of the projection exposure apparatuses 100, 200, provision is made of a plurality of source modules 3 for generating individual radiations 4, with the individual radiations 4 forming the used radiation 2.

Exactly two source modules 3 can be provided in the exemplary embodiment of the radiation source apparatus 1 depicted in FIG. 3.

The source modules 3 of the exemplary embodiment depicted in FIG. 3 can be switchable at least partly independently. To switch the source modules 3, a control device 5 can be present in the exemplary embodiment of the radiation source apparatus 1 depicted in FIG. 3.

In the exemplary embodiment of the radiation source apparatus 1 depicted in FIG. 3, the source modules 3 can be further arranged such that the used radiation 2 is output from the parallel and spaced-apart individual radiations 4 of the source modules 3.

In the radiation source apparatus 1 according to the exemplary embodiment depicted in FIG. 3, there also is a positioning device 6 which serves the purpose of positioning the source modules 3. In this case, for example, the source modules 3 are positionable at least partly independently of one another.

In the exemplary embodiment depicted in FIG. 3, provision can also be made of a mixing device 7 for mixing the used radiation 2 and having an entrance surface 14.

According to the exemplary embodiment depicted in FIG. 3, an interface device 8 for positioning and aligning the individual radiations 4 can be provided in the radiation source apparatus 1.

In this case, the interface device 8 can be configured to input couple the used radiation 2 into the mixing device 7.

FIG. 4 shows a schematic illustration of a possible embodiment of the source module 3 of the radiation source apparatus 1.

In the exemplary embodiment depicted in FIG. 4, the source module 3 comprises an ellipsoid mirror 9 for aligning the individual radiation 4. As an alternative or in addition, the source module 3 may also comprise one or more parabolic mirrors or a plurality of ellipsoid mirrors 9.

In the exemplary embodiment depicted in FIG. 4, the source module 3 can comprise a spectral filter 10 for filtering the individual radiation 4. A plurality of spectral filters 10 may also be provided.

In the exemplary embodiment depicted in FIG. 4, the source module 3 also comprises a light source 11, which can be in the form of a discharge lamp, such as a mercury vapor discharge lamp. A plurality of light sources 11 may also be provided.

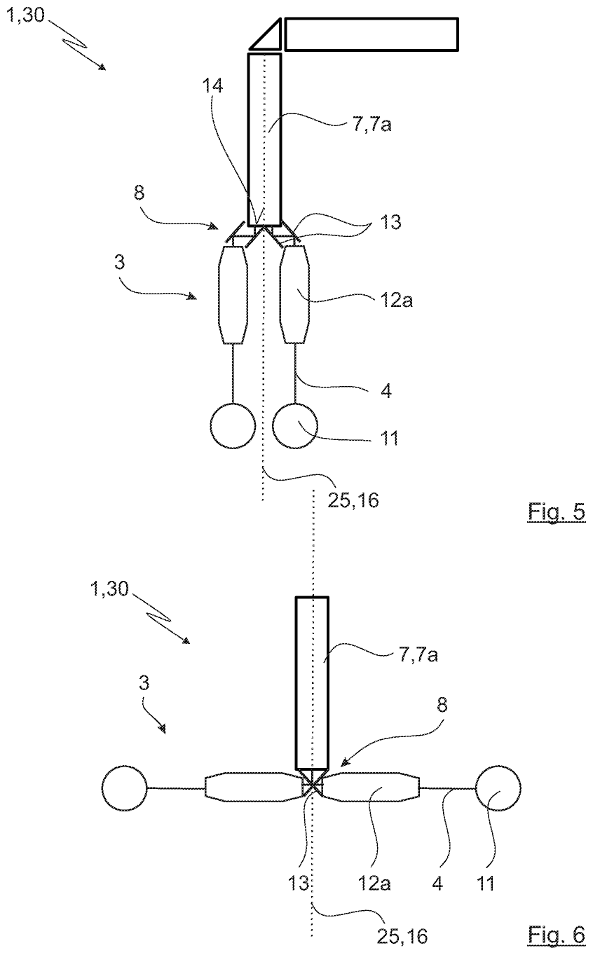

In the exemplary embodiment of the source module 3 depicted in FIG. 3, there also is an optical unit 12, which can be in the form of a scale zoom optical unit 12a and/or a focal length zoom optical unit 12b (cf. FIGS. 5 and 12). A plurality of optical units 12 may also be provided.

FIG. 5 shows a schematic illustration of a further possible embodiment of the radiation source apparatus 1.

In the exemplary embodiment illustrated in FIG. 5, the mixing device 7 is in the form of a mixing rod 7a.

In the exemplary embodiment depicted in FIG. 5, the source modules 3 are also spaced apart and arranged parallel to one another in the direction of their individual radiations 4, and the interface device 8 comprises four deflection mirrors 13, with the deflection mirrors being arranged parallel to one another in pairwise fashion, in such a way that the deflection results in a reduced spacing of the individual radiations 4 post incidence on the deflection mirrors 13. In this case, the deflection mirrors 13 can be arranged such that the deflected individual radiations 4 are guided at right angles to the entrance surface 14 of the mixing rod 7a.

FIG. 6 shows a schematic illustration of a further possible embodiment of the radiation source apparatus 1.

In the exemplary embodiment depicted in FIG. 6, the source modules 3 can be arranged in spaced apart fashion and, in the direction of their individual radiations 4, in antiparallel and laterally offset fashion.

Regarding the further reference signs, reference is made to FIG. 5.

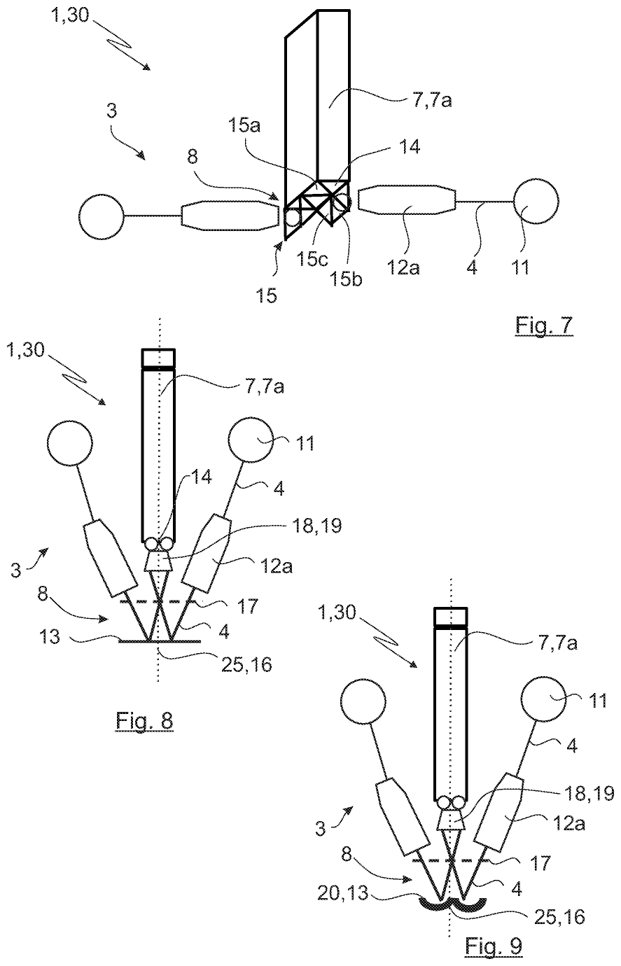

FIG. 7 shows a schematic illustration of a further possible embodiment of the radiation source apparatus 1.

In this case, the interface device 8 comprises two or more prisms 15, with the prisms 15 being arranged such that a respective first side face 15a of the prisms 15 is arranged at least approximately parallel to the entrance surface 14 of the mixing rod 7a. Further, a respective second side face 15b can be arranged at least approximately perpendicular to the individual radiations 4 and a respective third side face 15c is arranged such that the individual radiations 4 are guided from the respective second side face 15b to the respective first side face 15a within the respective prism 15.

FIG. 8 shows a schematic illustration of a further possible embodiment of the radiation source apparatus 1.

In the exemplary embodiment depicted in FIG. 8, the source modules 3 are arranged in spaced apart fashion and, in the direction of their individual radiations 4, tilted vis-à-vis one another and vis-à-vis a central plane 16 of the mixing rod 7a, in such a way that their respective scale zoom optical units 12a and/or focal length zoom optical units 12b have a common pupil plane 17. Further, the interface device 8 can comprise a Fourier optics device 18 as an input coupling group 19, which is configured to image the individual radiations 4 onto the entrance surface 14 of the mixing rod 7a.

In the exemplary embodiment depicted in FIG. 8, the interface device 8 can comprise one or more deflection mirrors 13, the deflection mirror 13 being arranged such that the individual radiations 4 are aligned with the Fourier optics device 18.

FIG. 9 shows a schematic illustration of a further possible embodiment of the radiation source apparatus 1 according to FIG. 8.

In comparison with the embodiment depicted in FIG. 8, the interface device 8 in FIG. 9 comprises a deflection device 20, with the deflection device 20 having optical powers that act on the individual radiation 4, for example for an adaptation of back focal lengths 21 (see FIG. 12). In this case, the deflection device 20 is arranged such that the individual radiations 4 are aligned with the Fourier optics device 18. In the exemplary embodiments depicted in FIGS. 5 to 9, the individual radiations 4 are able to be input coupled into the mixing rod 7a along the central plane of the mixing rod 7a.

In the exemplary embodiments depicted in FIGS. 7, 8, and 9, the images of the individual radiations 4 are depicted as circles in a region of the entrance surface 14.

FIG. 10 shows a schematic illustration of a conventional radiation source apparatus 1.

In the exemplary embodiment depicted in FIG. 10, the mixing device 7 is in the form of a fly's eye condenser 7b with a field honeycomb device 22, a pupil honeycomb device 23, and a downstream secondary Fourier optics device 24.

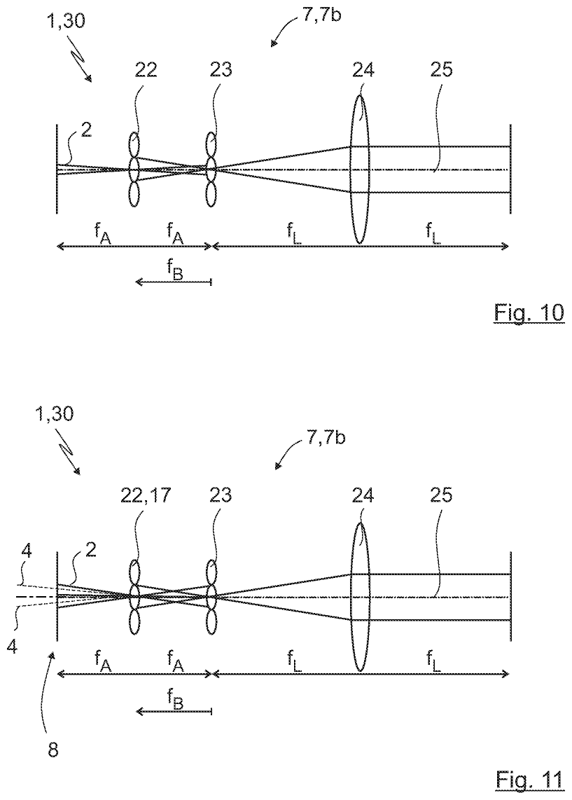

FIG. 11 shows a schematic illustration of a further possible embodiment of the radiation source apparatus 1 according to the disclosure, which builds on the radiation source apparatus 1 according to FIG. 10.

In the exemplary embodiment depicted in FIG. 11, the individual radiations 4 are tilted vis-à-vis one another and vis-à-vis an optical axis 25, in such a way that the individual radiations 4 are imaged into the field honeycomb device 22 and their respective focal length zoom optical units 12b (see FIG. 12) have a common pupil plane 17.

In the exemplary embodiments depicted in FIGS. 10 and 11, fA denotes a focal length of the field honeycomb device 22, fB denotes a focal length of the pupil honeycomb device 23, and fL denotes a focal length of the secondary Fourier optics device 24.

FIG. 12 shows a schematic illustration of a further possible embodiment of the radiation source apparatus 1.

In the exemplary embodiment depicted in FIG. 12, the source modules 3 can each comprise at least one focal length zoom optical unit 12b.

In the exemplary embodiment depicted in FIG. 12, the source modules 3 are arranged in spaced apart fashion and, in the direction of their individual radiations 4, arranged tilted vis-à-vis one another and vis-à-vis an optical axis 25, in such a way that the individual radiations 4 are imaged into the field honeycomb device 22 and their respective focal length zoom optical units 12b have a common pupil plane 17.

In the exemplary embodiment depicted in FIG. 12, the focal length zoom optical units 12b each comprise at least one retrofocus device.

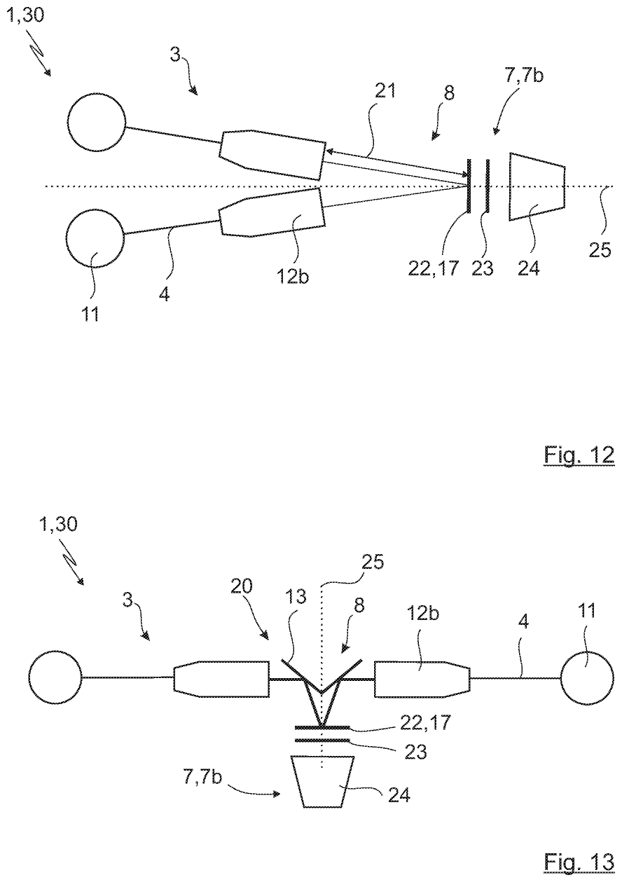

FIG. 13 shows a schematic illustration of a further possible embodiment of the radiation source apparatus 1.

In the exemplary embodiment depicted in FIG. 13, the source modules 3 are arranged in spaced apart fashion and, in the direction of their individual radiations 4, in antiparallel fashion. In the exemplary embodiment depicted in FIG. 13, images of the light sources 11 can be positioned with a lateral offset by the secondary Fourier optics 24 as a result of a different field angle. Further, the interface device 8 can comprise the deflection device 20 having at least two deflection mirrors 13, the deflection mirrors 13 being arranged such that the individual radiations 4 are merged on the field honeycomb device 22 in a manner tilted with respect to the optical axis 25. Further, the individual radiations 4 can be imaged into the field honeycomb device 22, and the focal length zoom optical units 12b of the source modules 3 have a common pupil plane 17.

In the exemplary embodiment depicted in FIG. 13, the interface device 8 accordingly can comprise at least one deflection mirror 13, the deflection mirror 13 being arranged such that the individual radiations 4 are merged on the field honeycomb device 22.

In the exemplary embodiments depicted in FIGS. 12 and 13, the back focal length 21 of the respective focal length zoom optical unit 12b is formed such that it corresponds to at least one image diameter, such as three times the image diameter, for example ten times the image diameter, of the respective individual radiations 4 at the field honeycomb device 22.

Together with the respective mixing device 7, 7a, 7b, the radiation source apparatus 1 depicted in FIGS. 3 to 13 forms at least one part of an illumination system 30 for a lithography system, for example for one of the projection exposure apparatuses 100, 200.

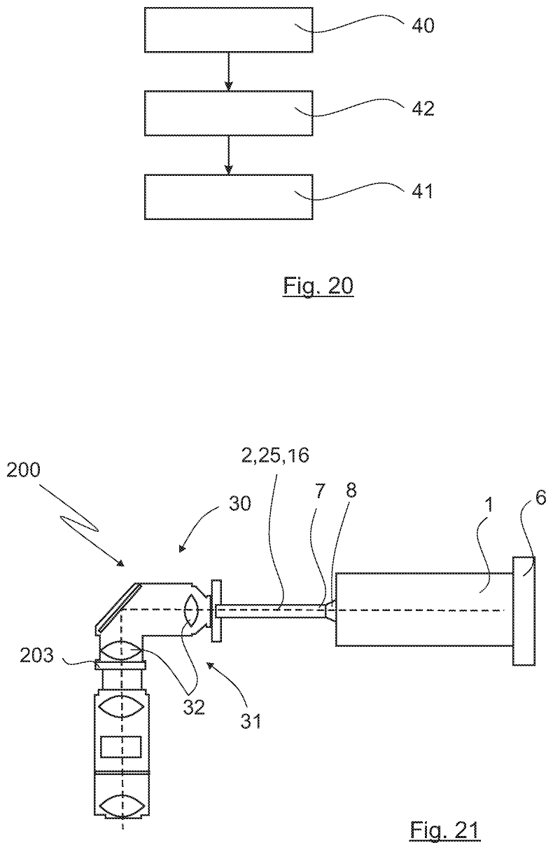

The illumination system 30 serves to illuminate a reticle 106, 203 of the lithography system using the used radiation 2 from the radiation source apparatus 1. It comprises an optics device 31 (see FIG. 21) having at least one optical element 32 (see FIG. 21) and at least one mixing device 7. Further, provision is made of the interface device 8 for input coupling the plurality of individual radiations 4, which form the used radiation 2, into the mixing device 7.

In the exemplary embodiments illustrated in FIGS. 5 to 9, the mixing device 7 is in the form of a mixing rod 7a. Further, at the entrance surface 14 of the mixing rod 7a, the individual radiations 4 are offset from one another and, with respect to the central axis 16 of the mixing rod, offset parallel thereto and from one another.

According to the exemplary embodiments depicted in FIGS. 11 to 13, the mixing device 7 is in the form of a fly's eye condenser 7b with the field honeycomb device 22, the pupil honeycomb device 23, and the downstream secondary Fourier optics device 24.

The interface device 8 is further configured to input couple a plurality of individual radiations 4 of the used radiation 2 into the fly's eye condenser 7b, with the individual radiations 4 being tilted with respect to one another and with respect to an optical axis 25 of the fly's eye condenser 7b at the field honeycomb device 22 and being merged there.

According to the exemplary embodiments of the illumination system 30 depicted in FIGS. 5, 6, 8, 9, and 13, the interface device 8 comprises at least one deflection mirror 13 with optical power.

According to the exemplary embodiment depicted in FIG. 7, the interface device 8 comprises at least one prism 15, which may have optical power.

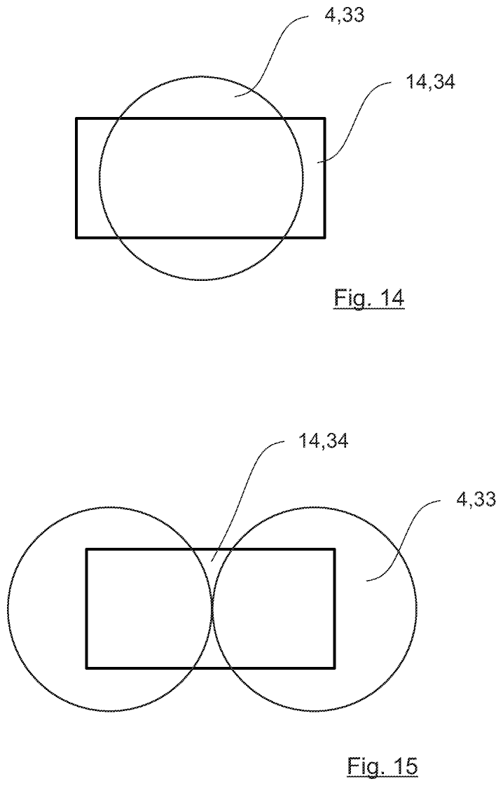

FIG. 14 shows an entrance surface 14 of a mixing device 7 and an individual radiation 4. A possible ratio of a source étendue 33 of the radiation source device 1 to an optics étendue 34 of the optics device 31 and/or mixing device 7 of the illumination system 30 in a conventional illumination system is shown schematically.

In the conventional illumination system, the optics étendue 34 is not completely filled by the source étendue 33. The possible étendue is not exploited to the full, whereby an inadequate luminous intensity may arise at the reticle 106, 203.

In the exemplary embodiments depicted in FIGS. 3 to 9 and 11 to 13, the radiation source apparatus 1 of the illumination system 30 is in the form of a radiation source apparatus 1 according to the disclosure, as described in the context of FIGS. 3 to 13.

In the exemplary embodiment depicted in FIG. 3, in the case of the illumination system 30, the positioning device 6 is further present and configured for positioning the illumination system 30, for example relative to the radiation source apparatus 1, and/or for positioning the radiation source apparatus 1, for example relative to the illumination system 30.

FIG. 15 shows a schematic illustration of a possible ratio of a source étendue 33 of the radiation source device 1 to an optics étendue 34 of the illumination system 30 in the illumination system 30 or in the case of the radiation source apparatus 1 as explained in the context of FIGS. 3 to 13.

In the exemplary embodiment of the illumination system 30 depicted in FIG. 15, the source étendue 33 of the radiation source apparatus 1 fills at least 50 percent, such as at least 80 percent, of an optics étendue 34 of the optics device 31 and/or mixing device 7.

A control device not depicted here can be configured to set the number of light sources 11 or individual radiations 4 to be used, in such a way that the usable power of all source modules 3 or light sources 11 η_{N} is greater than the usable power of an individual source module 3 η₁. The usable powers η_{N} and η₁ are specified in formulas (2) and (3).

$${η}_{1} = {\int }_{S} dSP ( x , y ) \qquad ( 2 )$$

$${η}_{N} = {\sum }_{i = 1}^{N} {\int }_{S} {dSP}_{i} ( x , y ) \qquad ( 3 )$$

In formulas (2) and (3), Pᵢ(x,y) denotes an image of an i-th light source 11 on the entrance surface 14, where x and y represent Cartesian coordinates in the image plane. In formulas (2) and (3), dS represents a surface element, the integration being implemented over a surface S which can correspond to the entrance surface 14.

FIG. 16 shows a schematic illustration of a possible improvement of an exploitation of the optics étendue 34 by the source étendue 33 by way of the radiation source apparatus 1 according to the disclosure or the illumination system 30 according to the disclosure in the case of an elongate scanner configuration of the illumination field on the reticle 106, 203.

On the left, a desired large illumination setting 26 is depicted by way of a broad cone and the position of the beam cross section of the used radiation 2 in the entrance surface 14 of the mixing rod 7a according known technology.

On the right, the position of the beam cross section of the used radiation 2 in the entrance surface 14 of the mixing rod 7a is depicted in the case of the radiation source apparatus 1 or illumination system 30. In this case, the used radiation 2 is formed by a plurality of individual radiations 4, such as by a total of two, leading to a better exploitation of the optics étendue 34 and hence a greater luminous intensity at the reticle 106, 203.

In the case of the embodiment in the scanner configuration depicted in FIG. 16, the étendue can be exploited more efficiently than in known systems by way of two at least approximately identical, parallel, and spaced-apart individual radiations 4.

FIG. 17 shows a schematic illustration of a possible improvement of a conventional exploitation of the optics étendue 34 by the source étendue 33, depicted to the left, by way of the radiation source apparatus 1 according to the disclosure or the illumination system 30 according to the disclosure in the case of a square stepper configuration of the illumination field on the reticle 106, 203, in a manner analogous to FIG. 16.

In the case of the embodiment in the stepper configuration depicted to the right in FIG. 17, the étendue can be exploited more efficiently than in known systems by way of four at least approximately identical, parallel, and spaced-apart individual radiations 4 which are arranged at least approximately in square fashion.

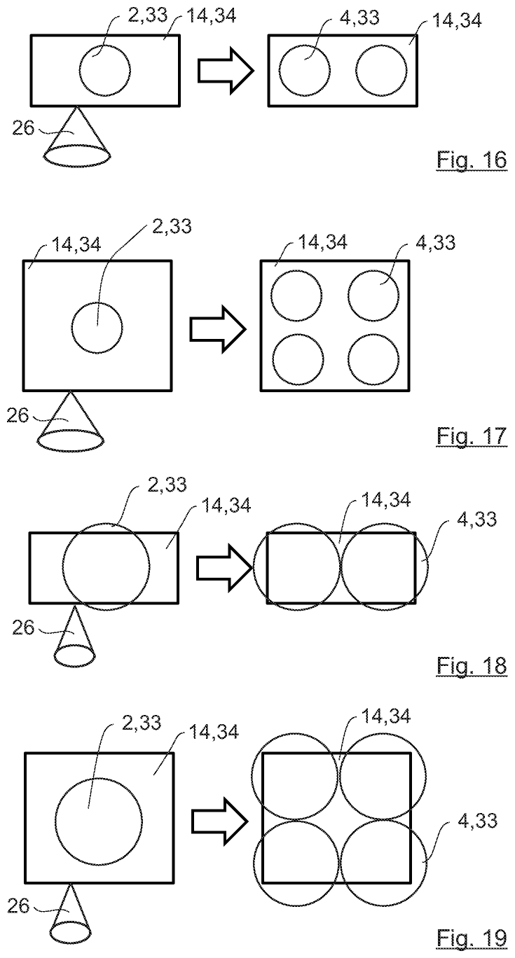

FIG. 18 shows a schematic illustration of a possible improvement of an exploitation of the optics étendue 34 by the source étendue 33 by way of the radiation source apparatus 1 according to the disclosure or the illumination system 30 according to the disclosure in the case of an elongate scanner configuration of the illumination field on the reticle 106, 203, in a manner analogous to FIG. 16.

On the left, the desired small illumination setting 26 is depicted by way of a narrow cone and the position of the beam cross section of the used radiation 2 in the entrance surface 14 of the mixing rod 7a according to known technology.

On the right, the position of the beam cross section of the used radiation 2 in the entrance surface 14 of the mixing rod 7a is depicted in the case of the radiation source apparatus 1 or illumination system 30. In this case, the used radiation 2 is formed by a plurality of individual radiations 4, such as by a total of two, leading to a better exploitation of the optics étendue 34 and hence a greater luminous intensity at the reticle 106, 203. In this case, the entrance surface 14 is overfilled, leading to a loss of light. Compared to the known approach depicted on the left, there still is, however, an increased illuminance at the reticle 106, 203.

FIG. 19 shows a schematic illustration of a possible improvement of a conventional exploitation of the optics étendue 34 by the source étendue 33, depicted to the left, by way of the radiation source apparatus 1 according to the disclosure or the illumination system 30 according to the disclosure in the case of a square scanner configuration of the illumination field on the reticle 106, 203, in a manner analogous to FIG. 17. However, a smaller illumination setting 26 is desired in the exemplary embodiment depicted in FIG. 19.

In the case of the embodiment in the stepper configuration depicted to the right in FIG. 19, the étendue can be exploited more efficiently than in known systems by way of four at least approximately identical, parallel, and spaced-apart individual radiations 4 which are arranged at least approximately in square fashion and which overfill the entrance surface 14.

FIG. 20 shows a block diagram illustration of a possible embodiment of a method for illuminating the reticle 106, 203 of the lithography system.

In the method for illuminating the reticle 106, 203 of the lithography system, for example of the projection exposure apparatus 100, 200, using the used radiation 2, the individual radiations 4 for forming the used radiation 2 are generated in a generation block 40 by the plurality of source modules 3.

In an input coupling block 41, the individual radiations 4 are input coupled into the mixing device 7 of the projection exposure apparatus 100, 200.

In an optional switching block 42, the source modules 3 can be switched and/or positioned in at least partly independent fashion.

Within the scope of the input coupling block 41, provision can be made for the individual radiations 4 to be input coupled into the mixing device 7 optionally in the form of a mixing rod 7a, in such a way that, at the entrance surface 14 of the mixing rod 7a, the individual radiations 4 are offset from one another and, with respect to the optical axis 25 of the mixing rod 7a, offset parallel thereto and from one another.

To form the used radiation 2 in a mixing device 7 in the form of a fly's eye condenser 7b having a field honeycomb device 22, a pupil honeycomb device 23, and a downstream secondary Fourier optics device 24 within the scope of the input coupling block 41, provision can be alternatively or additionally made for the individual radiations 4 to be input coupled in such a way that the individual radiations 4 are tilted with respect to one another and with respect to the optical axis 25b of the fly's eye condenser 7b at the field honeycomb device 22 and are merged there.

Within the scope of the switching block 42, provision can be made for the source modules 3 to be switched and/or positioned in such a way that a source étendue 33 of the radiation source apparatus 1 fills at least 50 percent, such as at least 80 percent, of an optics étendue 34 of the projection exposure apparatus 100, 200 for each utilized pupil filling.

FIG. 21 shows a schematic illustration of a further possible embodiment of the projection exposure apparatus 200 according to the disclosure using the radiation source apparatus 1 and/or the illumination system 30.

In the lithography system depicted in FIGS. 1, 2, and 21, for example in the projection exposure apparatus 100, 200, having the radiation source apparatus 1 and/or the illumination system 30 for illuminating the reticle 106, 203 with the used radiation 2, provision is made for the radiation source apparatus 1 to be the radiation source apparatus 1 explained in the context of FIGS. 3 to 19, and/or for the illumination system 30 to be the illumination system 30 explained in the context of FIGS. 3 to 19, and/or for the reticle 106, 203 to be illuminated by the method explained in the context of FIG. 20.

In the lithography system, the positioning device 6 can be provided and configured to position the source modules 3 relative to one another and/or relative to the illumination system 30, and/or to position the radiation source apparatus 1 relative to the illumination system 30.

### LIST OF REFERENCE SIGNS

1 Radiation source apparatus
2 Used radiation
3 Source module
4 Individual radiation
5 Control device
6 Positioning device
7 Mixing device
7a Mixing rod
7b Fly's eye condenser
8 Interface device
9 Ellipsoid mirror
10 Spectral filter
11 Light source
12 Optical unit
12a Scale zoom optical unit
12b Focal length zoom optical unit
13 Deflection mirror
14 Entrance surface
15 Prism
15a First side face
15b Second side face
15c Third side face
16 Central plane
17 Pupil plane
18 Fourier optics device
19 Input coupling group
20 Deflection device
21 Back focal length
22 Field honeycomb device
23 Pupil honeycomb device
24 Secondary Fourier optics device
25 Optical axis
26 Illumination setting
30 Illumination system
31 Optics device
32 Optical element
33 Source étendue
34 Optics étendue
40 Generation block
41 Input coupling block
42 Switching block
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens
208 Mount
209 Lens housing
210 Projection beam
Mi Mirrors

What is claimed is:

1. An illumination system configured to illuminate a reticle of a lithography system with a used radiation from a radiation source apparatus, the illumination system comprising:
an optics device, comprising:
an optical element;
a mixing device; and
an interface device configured to input couple a plurality of individual radiations into the mixing device, the plurality of individual radiations formed from the used radiation,
wherein the illumination system is configured so that a source étendue of the radiation source apparatus fills at least 50 percent of an optics étendue of the optics device and/or mixing device.

2. The illumination system of claim 1, wherein the mixing device comprises a mixing rod.

3. The illumination system of claim 2, wherein the illumination system is configured so that:
the individual radiations are offset from one another at an entrance surface of the mixing rod; and
the individual radiations are offset parallel to an optical axis of the mixing rod and from one another.

4. The system of claim 1, wherein:
the mixing device comprises a fly's eye condenser; and
the fly's eye condenser comprises a field honeycomb device, a pupil honeycomb device, and a downstream secondary Fourier optics device.

5. The illumination system of claim 4, wherein the interface device is configured to input couple a plurality of individual radiations of the used radiation into the fly's eye condenser with the individual radiations being tilted with respect to one another and with respect to an optical axis of the fly's eye condenser at the field honeycomb device and being merged there.

6. The illumination system of claim 1, wherein the interface device comprises a deflection mirror.

7. The illumination system of claim 1, comprising a radiation source apparatus, wherein the radiation source apparatus comprises a plurality of source modules configured to generate individual radiations that form the used radiation.

8. A lithography system, comprising:
an illumination system according to claim 1.

9. The lithography system of claim 8, comprising the radiation source apparatus, wherein the radiation source apparatus comprises a plurality of source modules configured to generate individual radiations that form the used radiation.

10. The illumination system of claim 1, further comprising a positioning device configured to position the illumination system and/or the radiation source apparatus relative to the illumination system.

11. A radiation source apparatus configured to provide used radiation, the radiation source apparatus comprising:
a plurality of source modules configured to generate individual radiations that form the used radiation.

12. The radiation source apparatus of claim 11, wherein the plurality of source modules comprise two source modules.

13. The radiation source apparatus of claim 11, wherein the source modules are at least partly independently switchable.

14. The radiation source apparatus of claim 13, further comprising a control device configured to switch the source modules.

15. The radiation source apparatus of claim 11, wherein the source modules are configured so that the used radiation is output from the parallel and spaced-apart individual radiations of the source modules.

16. The radiation source apparatus of claim 11, further comprising a positioning device configured to position the source modules.

17. The radiation source apparatus of claim 11, wherein the source modules are positionable at least partly independently from one another.

18. The radiation source apparatus of claim 11, wherein each source modules comprises at least one member selected from the group consisting of:
a mirrors and/or an ellipsoid mirror configured to align the individual radiations;
a spectral filter configured to filter the individual radiations,
a light source; and
an optical unit.

19. The radiation source apparatus of claim 11, further comprising a mixing device configured to mix the used radiation, the mixing device having an entrance surface.

20. A lithography system, comprising:
a radiation source according to claim 11.

21. A method for illuminating a reticle of a lithography system with a used radiation, the method comprising:
using a plurality of source modules to generate individual radiations for forming the used radiation; and
input coupling the individual radiations into a mixing device of the lithography system.
